(19) United States
(12) Patent Application Publication
(10) Pub. No.: US 2011/0309409 A1
(43) Pub. Date: Dec. 22, 2011

(54) SEMICONDUCTOR DEVICE

(75) Inventor: Takashi Yamazaki, Kanagawa (JP)

(73) Assignee: SONY CORPORATION, Tokyo (JP)

(21) Appl. No.: 13/157,845

(22) Filed: Jun. 10, 2011

(30) Foreign Application Priority Data
Jun. 18, 2010 (JP) 2010-139851

(51) Int. Cl. H01L 29/74

(52) U.S. Cl. 257/146; 257/E29.211

(57) ABSTRACT

A semiconductor device includes: a semiconductor substrate having an electronic circuit including a power supply line and a ground line formed thereon; and an electrostatic discharge protection element provided between the power supply line and the ground line on the semiconductor substrate, the electrostatic discharge protection element including a thyristor and a trigger diode driving the thyristor, wherein the trigger diode includes an anode diffusion layer formed on the semiconductor substrate, a cathode diffusion layer formed on the semiconductor substrate apart from the anode diffusion layer, and a gate electrode formed between the anode diffusion layer and the cathode diffusion layer on the semiconductor substrate, a gate insulation film being interposed between the semiconductor substrate and the trigger diode, and an external terminal to be connected to an external power supply is electrically connected to the gate electrode.

### FIELD

The preset disclosure relates to a semiconductor device and, more particularly, to a semiconductor device or LSI including an ESD protection element for protecting electronic circuits in the semiconductor LSI from electrostatic discharge (ESD).

### BACKGROUND

In general, an ESD protection element is provided to protect electronic circuits in a semiconductor LSI from a current attributable to electrostatic discharge (hereinafter abbreviated as “ESD”) flowing into the LSI.

Thyristors (silicon controlled rectifiers which will be hereinafter abbreviated as “SCRs”) having a four-layer p-n-p-n structure are widely used as ESD protection elements as thus described because of their high discharging capability.

When a gate current is made to flow from a gate of a thyristor to a cathode of the same, continuity is established between an anode and the cathode of the thyristor to allow a large current to flow through the same.

According to a known method, a thyristor is used as an ESD protection element by employing a trigger element for driving the thyristor.

JP-T-2008-507857 (Patent Document 1) and “Diode-Triggered SCR (DTSCR) for RF-ESD Protection of BiCMOS SiGe HBTs and CMOS Ultra-Thin Gate Oxides”, Markus P. J. Mergens et al., IEDM technical digest 2003, pp. 21.3.1-21.3.4 and “Speed optimized diode-triggered SCR (DTSCR) for RF ESD protection of ultra-sensitive IC nodes in advanced technologies”, Markus P. J. Mergens et al., IEEE Transaction on Device and Materials Reliability, Volume 5, Issue 3, September 2005, pp. 532-542 (Non-Patent Documents 1 and 2) disclose configurations in which diodes are used as trigger elements. Specifically, the number of diode stages is adjusted to adjust a voltage at which a base current flow through a thyristor serving as an ESD protection element or a voltage at which the ESD protection element starts operating.

FIG. 10 is a schematic sectional view of an STI (shallow trench isolation) type diode according to the related art used as a trigger element as described above.

An n-type well 101 is formed on a semiconductor substrate 100, and an STI film 102 is formed on the well. The STI film 102 is used as a film isolating an anode and a cathode from each other rather than the purpose of element isolation.

A cathode diffusion layer 103, which is a layer having an n-type impurity diffused therein, is formed around one end of the STI film 102. An anode diffusion layer 104, which is a layer having a p-type impurity diffused therein, is formed around another end of the STI film.

The cathode diffusion layer 103 is connected to an anode terminal to which a cathode voltage V_{C} (ground voltage of 0 V) is applied.

The anode diffusion layer 104 is connected to an anode terminal, and an anode voltage V_{A} which is a predetermined positive voltage is applied to the anode terminal.

A body voltage V_{B} is applied to the semiconductor substrate.

It is desirable to keep the resistance of an ESD protection element small. The reason is as follows. When static electricity flows into a semiconductor LSI and an ESD protection element starts operating, if the ESD protection element has high resistance, a voltage from a power supply lie increases. When the voltage is applied to internal circuits of the LSI connected in parallel, the internal circuits can be broken.

To cope with such a problem, JP-A-2009-111363 (Patent Document 2) discloses a configuration in which a gate type diode is used as a trigger element instead of an STI type diode. Thus, an on-state resistance can be kept small unlike a situation in which an ESD current flows under an STI diode.

In the case of a thyristor type ESD protection element having diodes serving as trigger elements, a problem can be caused by a leak current generated at the protection element when the chip associated with the element starts operating.

Such a leak current can be generated because the diodes are connected in series between the power supply and the ground and a forward voltage is applied to each of the diodes.

The forward voltage applied per diode stage has a value obtained by dividing the power supply voltage by the total number of diode stages.

Table 1 shows an example of a forward voltage applied per diode stage in each of exemplary combinations of the power supply voltage, the number of trigger diode stages, the number of holding diode stages, and the umber of diode stages in a thyristor.

TABLE 1

| | Case 1 | Case 2 | Case 3 |
|---|---|---|---|
| Power Supply Voltage Vdd [V] | 1.2 | 2.5 | 2.5 |
| Trigger Diode Stages | 1 | 3 | 4 |
| Holding Diode Stages | 1 | 3 | 1 |
| Diode Stages in Thyristor | 1 | 1 | 1 |
| Voltage (V) per Diode Stage | 0.40 | 0.36 | 0.42 |

As shown in Table 1, a greater leak current is generated at each diode or each ESD protection element when a chip operates, the higher the forward voltage applied per diode stage.

Although a leak current can be kept small by increasing the number of diode stages, when the number of diode stages is increased, the area occupied by ESD protection elements increases, and the manufacturing cost of the semiconductor chip can increase.

### SUMMARY

It is desirable to keep a leak current generated at ESD protection elements small when a chip operates after the power supply is turned on without increasing the area occupied by the ESD protection elements.

An embodiment of the present disclosure is directed to a semiconductor device including a semiconductor substrate having an electronic circuit including a power supply line and a ground line formed thereon and an electrostatic discharge protection element provided between the power supply line and the ground line on the semiconductor substrate, the electrostatic discharge protection element including a thyristor and a trigger diode driving the thyristor. The trigger diode includes an anode diffusion layer formed on the semiconductor substrate and a cathode diffusion layer formed on the semiconductor substrate apart from the anode diffusion layer, and a gate electrode formed between the anode diffusion layer and the cathode diffusion layer on the semiconductor substrate with a gate insulation film interposed between the semiconductor substrate and the trigger diode. An external terminal to be connected to an external power supply is electrically connected to the gate electrode.

The semiconductor device according to the embodiment includes a semiconductor substrate having an electronic circuit including a power supply line and a ground line formed thereon and an electrostatic discharge protection element provided between the power supply line and the ground line on the semiconductor substrate. The electrostatic discharge protection element includes a thyristor and a trigger diode driving the thyristor.

The trigger diode includes an anode diffusion layer formed on the semiconductor substrate and a cathode diffusion layer formed on the semiconductor substrate apart from the anode diffusion layer, and a gate electrode formed between the anode diffusion layer and the cathode diffusion layer on the semiconductor substrate with a gate insulation film interposed between the semiconductor substrate and the trigger diode. Further, an external terminal to be connected to an external power supply is electrically connected to the gate electrode.

In the semiconductor device according to the embodiment of the present disclosure, a leak current generated at the ESD protection element can be suppressed when the chip operates after the supply of power is started without increasing the area occupied by the ESD protection element.

### BRIEF DESCRIPTION OF THE DRAWINGS

FIG. 1A is an equivalent circuit diagram of an ESD circuit of a semiconductor device according to a first embodiment of the present disclosure;

FIG. 1B is a schematic sectional view of a trigger diode forming a part of the ESD circuit;

FIG. 2A is a schematic sectional view of the trigger diode of the semiconductor device according to the first embodiment taken before the power supply is turned on; FIG. 2B is a potential diagram representing operations of the semiconductor device;

FIG. 2C is a schematic sectional view of the trigger diode taken after the power supply is turned on;

FIG. 2D is a potential diagram representing operations of the semiconductor device;

FIGS. 3A and 3B are schematic sectional views showing a method of manufacturing the semiconductor device according to the first embodiment of the present disclosure;

FIGS. 4A and 4B are schematic sectional views showing the method of manufacturing the semiconductor device according to the first embodiment of the present disclosure;

FIGS. 5A to 5C are schematic sectional views showing the method of manufacturing the semiconductor device according to the first embodiment of the present disclosure;

FIGS. 6A and 6B show current-voltage characteristics associated with the embodiment of the present disclosure;

FIGS. 7A and 7B show current-voltage characteristics associated with the embodiment of the present disclosure;

FIGS. 8A and 8B show current-voltage characteristics associated with the embodiment of the present disclosure;

FIG. 9 is a schematic configuration diagram of a semiconductor device according to a second embodiment of the present disclosure; and

FIG. 10 is a schematic sectional view of an STI type diode according to the related art used as a trigger element.

### DETAILED DESCRIPTION

Embodiments of a semiconductor device and a method of manufacturing the same according to the present disclosure will now be described with reference to the drawings.

The following items will be described in the order listed.

1. First Embodiment (Basic Configuration)

2. Simulation Results

3. Second Embodiment (Configuration including a step-down circuit provided between a power supply line and a trigger diode)

### First Embodiment of the Present Disclosure

### [Configuration of Semiconductor Device]

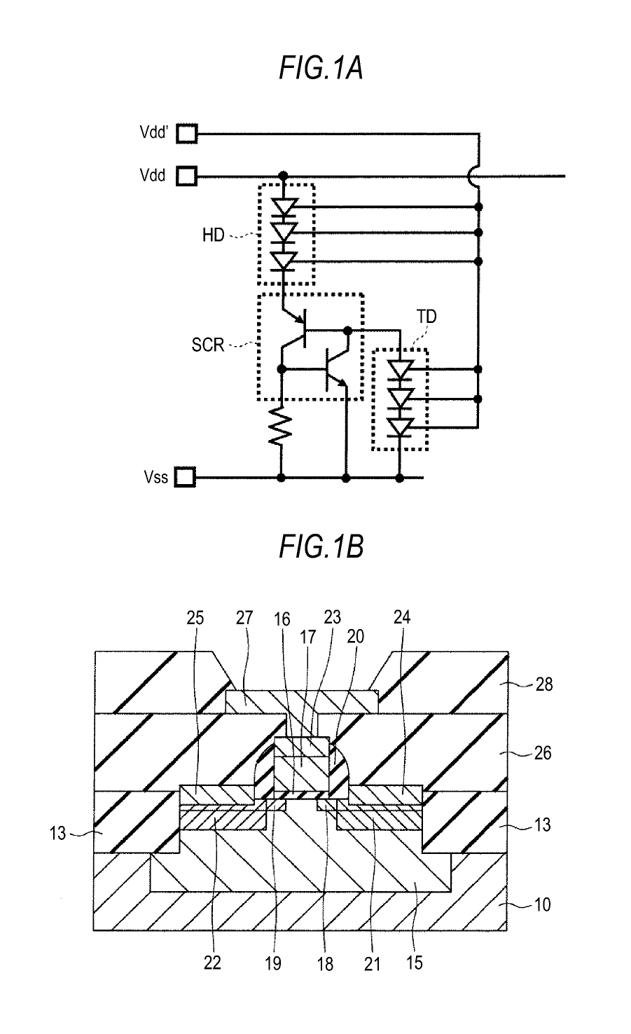

FIG. 1A is an equivalent circuit diagram of an ESD circuit of a semiconductor device according to a first embodiment of the present disclosure.

An electronic circuit (not shown) including a power supply line Vdd and a ground line Vss is formed on a semiconductor substrate.

An electrostatic discharge (ESD) protection element including a thyristor SCR and trigger diodes TD and holding diodes HD for driving the thyristor SCR is formed between the power supply line Vdd and the ground line Vss on the semiconductor substrate.

A power supply line Vdd′ is connected to the trigger diodes TD and the holding diodes HD. The power supply line Vdd′ is a power supply line separate from the power supply line Vdd to which the ESD protection element is connected.

FIG. 1B is a schematic sectional view of a trigger diode forming a part of the ESD circuit.

An STI (shallow trench isolation) element isolating insulation film 13 is formed so as to define an active region, which is to serve as a trigger diode, of a semiconductor substrate 10 that is, for example, a silicon substrate. An n-type well 15 is formed in the active region.

For example, a gate electrode 17 made of polysilicon is formed on the n-type well 15 of the semiconductor substrate 10 with a gate insulation film 16 made of a silicon oxide interposed between the well and the electrode. Sidewall insulation films 20 made of a silicon oxide are formed on both sides of the gate electrode 17.

For example, an n-type extension diffusion layer 18 and an n-type cathode diffusion layer 21 are formed in the semiconductor substrate 10 on one side of the gate electrode 17 so as to extend below the gate electrode 17.

A p-type extension diffusion layer 19 and a p-type anode diffusion layer 22 are formed in the semiconductor substrate 10 on the other side of the gate electrode 17 so as to extend below the gate electrode 17.

As thus described, the n-type cathode diffusion layer 21 and the p-type anode diffusion layer 22 are formed apart from each other, and a gate type diode is formed by the cathode diffusion layer 21, the anode diffusion layer 22, and the gate electrode 17 formed on the semiconductor substrate 10 between the diffusion layers with the gate insulation film 16 interposed between the electrode and the substrate.

For example, layers 23, 24, and 25 of a high melting point metal silicide such as NiSi are formed on the top of the gate electrode 17, the cathode diffusion layer 21, and the anode diffusion layer 22, respectively.

A first insulation film 26 made of a silicon oxide is formed to cover the entire top surface of the gate type diode.

The first insulation film 26 has a contact which is an opening extending up to the high melting point metal silicide layer 23 on the gate electrode 17. A pad electrode 27 is formed so as to fill the contact, and the pad electrode is therefore connected to the gate electrode 17.

For example, a second insulation electrode 28 made of a silicon oxide is formed on the first insulation film 26 so as to leave an opening in the region of the pad electrode 27.

A part of the pad electrode 27 is exposed at the opening provided in the second insulation film 28 as described above, and the electrode therefore serves as an external terminal which can be connected to an external power supply. That is, an external terminal to be connected to an external power supply is electrically connected to the gate electrode 17.

### [Operations of Semiconductor Device]

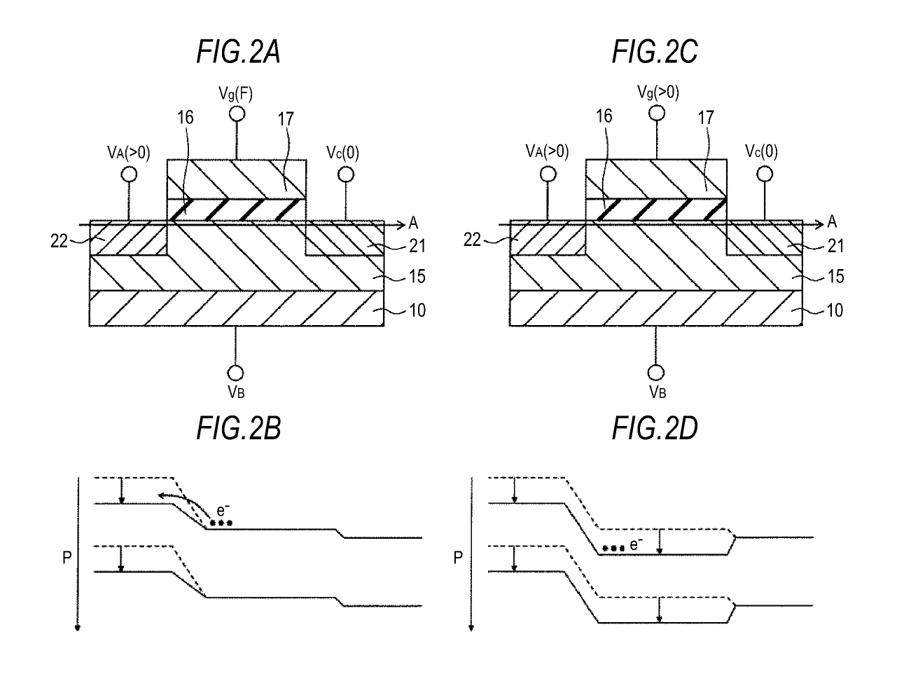

FIG. 2A is a schematic sectional view of a trigger diode of the semiconductor device according to the present embodiment taken before the power supply is turned on. FIG. 2B is a potential diagram representing operations of the device. FIG. 2B shows a potential in the direction indicated by the arrow A in FIG. 2A.

FIG. 2C is a schematic sectional view of the trigger diode taken after the power supply is turned on, and FIG. 2D is a potential diagram representing operations of the device. FIG. 2D shows a potential in the direction indicated by the arrow A in FIG. 2C.

The cathode diffusion layer 21 of the gate type diode shown in FIG. 1B is connected to a cathode terminal to which a cathode voltage V_{C} (ground voltage of 0 V) is applied.

The anode diffusion layer 22 is connected to an anode terminal, and an anode voltage V_{A}, which is a predetermined positive voltage, is applied to the terminal.

A body voltage V_{B} is applied to the semiconductor substrate 10.

Further, a pad electrode 27 is connected to the gate electrode 17.

The power supply line Vdd′ separate from the power supply line Vdd connected to the ESD protection element is connected to the pad electrode. Before the supply of power to the semiconductor device is started, the power supply line Vdd′ is in a floating state in which no voltage is applied. After the supply of power is started, a voltage Vdd′ is applied. For example, the voltage Vdd′ is a voltage lower than a voltage Vdd from the power supply lie Vdd.

An STI type diode having a p-type diffusion layer and an n-type diffusion layer isolated by an STI region according to the related art is disadvantageous in that a current is likely to flow from an anode terminal into the diode via a region under the STI region.

The gate electrode of the gate-type diode of the present embodiment is in a floating state as shown in FIGS. 2A and 2B before the power supply of the semiconductor device is turned on. A predetermined positive voltage is applied to the anode diffusion layer 22, and the layer therefore has a potential which is similar to a potential under the gate electrode. Thus, electrons e⁻ may flow toward the anode beyond the predetermined potential.

The gate-type diode of the present embodiment is different from a STI type diode in that the current flowing from the anode terminal into the diode does not pass below the STI region. Therefore, the diode has an on-state resistance smaller than that encountered in an STI type diode according to the related art.

After the power supply of the semiconductor device is turned on, a predetermined positive voltage is applied to the gate electrode as shown in FIGS. 2C and 2D. Thus, control is exercised to reduce the potential in the region of the substrate under the gate electrode 17.

As a result, the net value of a voltage applied to the PN junction of the diode is kept smaller than the value of such a voltage applied when no voltage is applied to the gate electrode, and a leak current flowing into the diode can therefore be suppressed.

A voltage is applied to the gate electrode to control the potential at the region of the substrate under the gate insulation film, whereby the on-state voltage of the diode can be increased to suppress a leak current.

In the semiconductor device of the present embodiment, a leak current per diode stage can be suppressed when the chip starts operating without increasing the area occupied by the ESD protection elements. Thus, a leak current generated at the ESD protection elements can be suppressed.

### [Method of Manufacturing Semiconductor Device]

A method of manufacturing a semiconductor device according to the embodiment of the present disclosure will now be described.

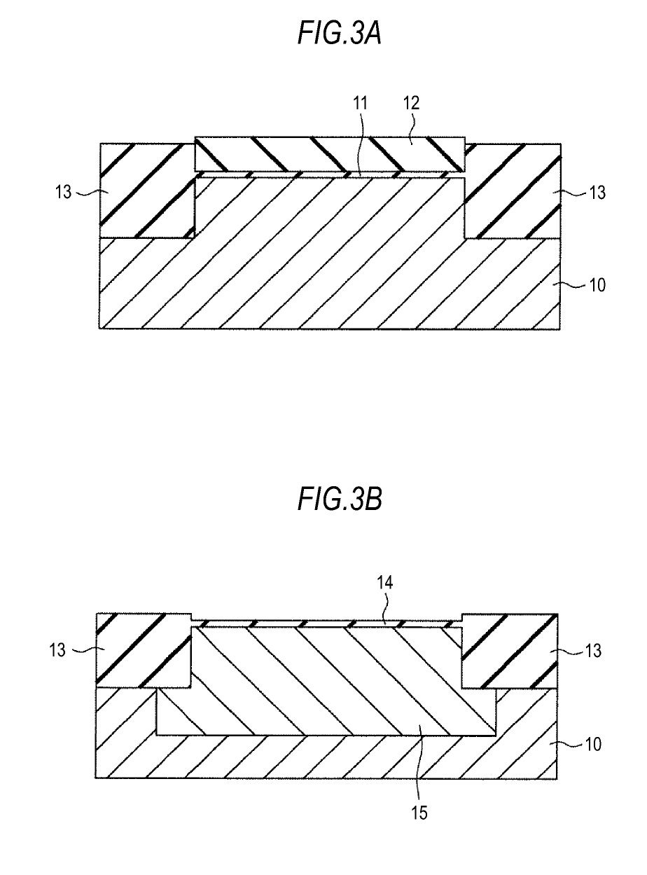

FIGS. 3A to 5C are schematic sectional views showing a method of manufacturing a semiconductor device according to the embodiment of the present disclosure. FIGS. 3A to 5C are sectional views corresponding to the sectional view shown in FIG. 1B.

First, a silicon oxide film 11 and a silicon nitride film 12 are formed on a semiconductor substrate 10 using, for example, a CVD process as shown in FIG. 3A, and a photolithographic step is performed to provide a resist film patterned to protect an active region.

Next, an etching process such as RIE (reactive ion etching) is performed using the resist film as a mask to remove the silicon oxide film 11 and the silicon nitride film 12 except in the active region. Further, the semiconductor substrate 10 is etched to a depth of, for example, 300 to 400 nm to form a groove to be used for STI.

Next, a high-density plasma CVD process is performed to embed an STI material in the substrate to form a silicon oxide film. The use of a high-density plasma CVD process allows the formation of a fine film having high step coverage.

Next, the silicon oxide outside the groove for STI is removed to form an STI element isolating insulation film 13. A CMP (chemical mechanical polishing) process is performed to polish the silicon oxide film from a top surface thereof until a top surface of the silicon nitride film 12 is exposed and to planarize the resultant surface.

Next, as shown in FIG. 3B, the silicon nitride film 12 and the silicon oxide film are removed using, for example, a thermal phosphate treatment.

Next, a sacrifice silicon oxide film 14 having a thickness of 10 nm is formed o a surface of the active region of the semiconductor substrate 10 using, for example, a thermal phosphate treatment.

An n-type well 15 is formed through the sacrifice silicon oxide film 14.

Similarly, ion implantation is carried out to adjust a threshold Vth of NTr, and ion implantation is also carried out to form a p-type well and to adjust a threshold Vth of PTr.

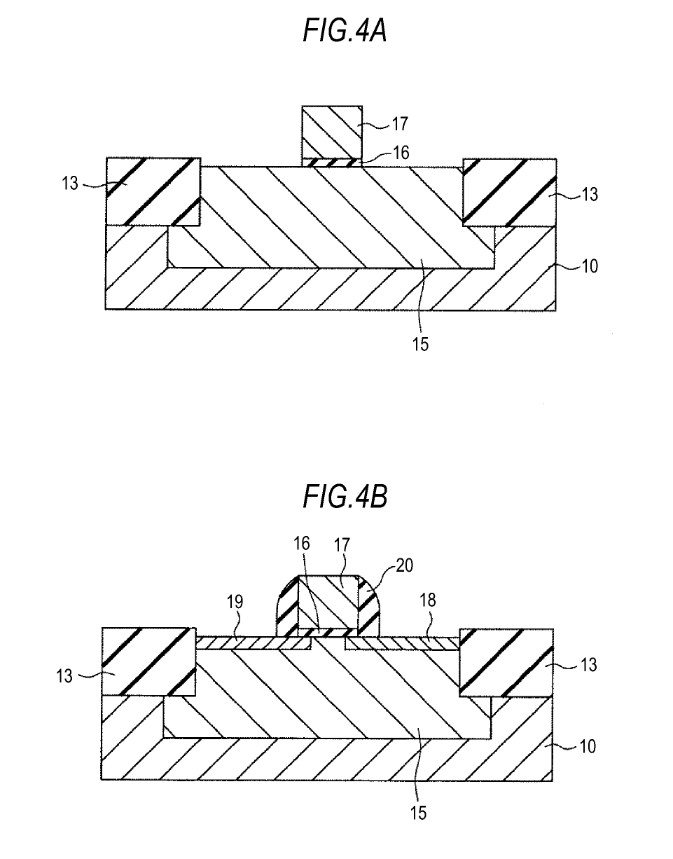

As shown in FIG. 4A, the sacrifice silicon oxide film 14 is removed using, for example, a hydrofluoric acid treatment. Further, a thermal oxidation treatment is carried out in dry O₂ ambient at 700° C. to form a silicon oxide film having a thickness of about 6 to 7 nm to serve as a gate insulation film 16.

A mixed gas such as H₂/O₂, N₂O, or NO may be used as the oxidation gas instead of O₂. Alternatively, a furnace annealing process or an RTA rapid thermal annealing) process may be performed.

A plasma nitridation technique may alternatively used to dope the oxide film with nitrogen. At this time, separate gate oxide films having different thicknesses, e.g., 2 nm and 5 nm may be formed to provide separate MOSFETs having different applied voltages and threshold voltages in the substrate plane.

For example, a low-pressure CVD process may be thereafter performed to form a polysilicon film having a thickness in the range from 100 to 150 nm. The low-pressure CVD process may be performed, for example, using SiH₄ as a material gas at a deposition temperature in the range from 580 to 620° C.

Subsequently, a silicon nitride to be used as a hard mask is deposited to a thickness, for example, in the range from about 50 to 100 nm using a CVD process.

After pattering a resist using lithography, anisotropic etching is performed using the resist as a mask to pattern the polysilicon into a gate electrode 17.

After the resist is patterned, a trimming process may be performed using O₂ plasma to form the polysilicon gate electrode with a small width. For example, a CMOS according to the 90-nm node technology has a gate length of about 70 nm.

Next, as shown in FIG. 4B, patterning is performed to form a resist film for protecting a region to become an anode region, and 10 keV As⁺ ions are implanted in a dose of 2×10¹⁴/cm² to form an n-type extension diffusion layer 18.

Patterning is performed to form a resist film for protecting a region to become a cathode region, and 5 Key BF₂⁺ ions are implanted in a dose of 3×10¹⁴/cm² to form a p-type extension diffusion layer 19.

Next, a CVD process is performed using, for example, TEOS (tetraethyl ortho silicate) as a material gas to deposit a silicon oxide throughout the substrate surface, and an anisotropic etch back process is performed on the surface excluding regions on both sides of the gate electrode 17. Thus, sidewall insulation films 20 are formed.

The sidewall length is determined by the thickness of insulation films such as TEOS oxide films, and the thickness may be in the range from 50 to 150 nm.

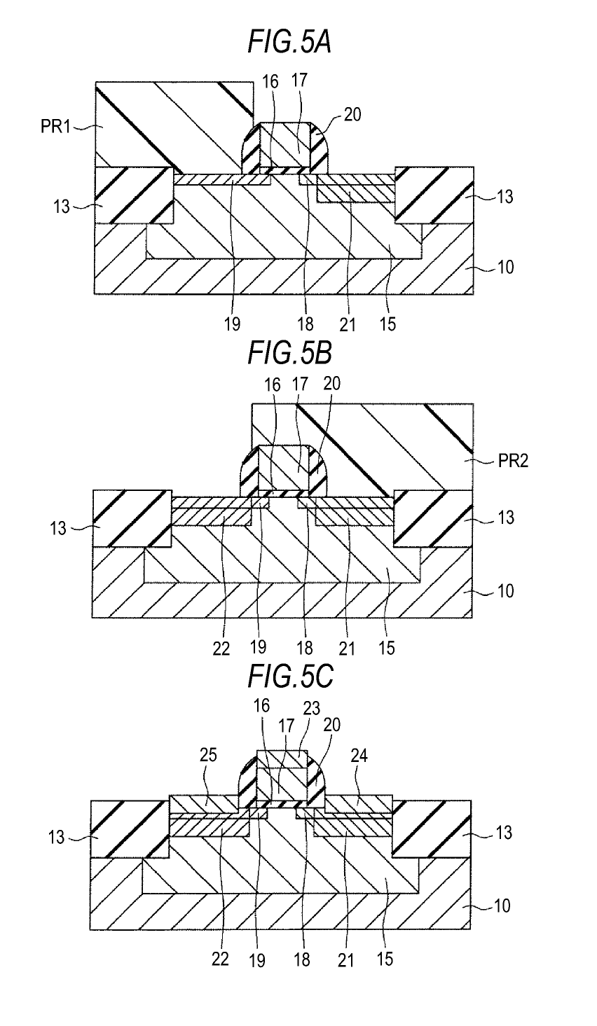

Next, as shown in FIG. 5A, pattering is performed to form a resist film PR1 for protecting a region to become an anode region, and 20 KeV P⁺ ions are implanted in a dose of 4×10¹³/cm² to form an n-type cathode diffusion layer 21. Normally, P⁺ which is an n-type impurity is also introduced into the gate electrode 17.

Next, as shown in FIG. 5B, patterning is performed to from a resist film PR2 for protecting a region to become the anode region and the gate electrode, and 5 keV B⁺ ions are implanted in a dose of 4×10¹⁵/cm² to form a p-type anode diffusion layer 22.

Next, an RTA process is performed at 1000° C. for 5 sec. to activate impurities. Alternatively, annealing can be carried out through a spike RTA process at 1050° C. for 0 sec. for the purpose of promoting dopant activation and suppressing diffusion.

Next, as shown in FIG. 5C, sputtering may be performed to deposit Ni to a thickness of about 8 nm throughout the surface.

Next, an RTA process is performed at 350° C. for 30 sec. to silicide only regions of the semiconductor substrate in contact with silicon on a self-alignment basis.

Thus, layers 23, 24, and 25 of a high melting point metal silicide such as NiSi are formed on the top of the gate electrode 17, the cathode diffusion layer 21, and the anode diffusion layer 22, respectively.

Next, unreacted Ni is removed using H₂SO₄/H₂O₂.

Subsequently, an RTA process is performed at 500° C. for 30 sec. to reduce the resistance of the layers 23, 24, and 25 of a high melting point metal silicide such as NiSi.

A layer of NiSi₂ may be formed by depositing NiPt. Other silicide materials such as cobalt and titanium may be used. In any case, RTA temperature can be set appropriately.

### <Simulation Results>

Results of a simulative analysis of a semiconductor device as described above will now be described.

The device has a configuration in which a p-type anode diffusion layer and an n-type cathode diffusion layer are formed in an n-type well region. Alternatively, the device may have a configuration in which a p-type anode diffusion layer and an n-type cathode diffusion layer are formed in a p-type well region.

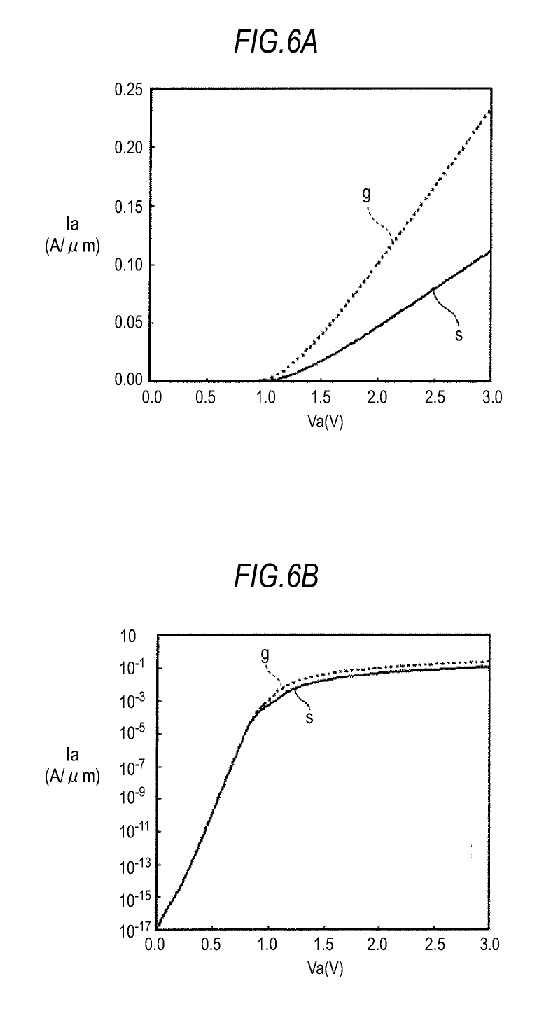

FIGS. 6A and 6B show current-voltage characteristics associated with the embodiment of the present disclosure.

The figures show a comparison between current (Ia)-voltage (Va) characteristics of an STI type diode (s) and a gate-type diode (g). The gate-type diode (g) has a lower on-state resistance. The gate terminal of the gate-type diode is in a floating state.

For example, a CMOS according to the 90 nm node technology has a minimum STI length of about 200 nm, and calculations have been made on an assumption that the STI type diode has an STI length of 200 nm.

The gate type diode has a gate length of 300 nm and a sidewall length of 120 nm, and the distance between the p-type anode diffusion layer and the n-type cathode diffusion layer is 540 nm.

Further, the on-state resistance of the gate type diode can be reduced by reducing the gate length.

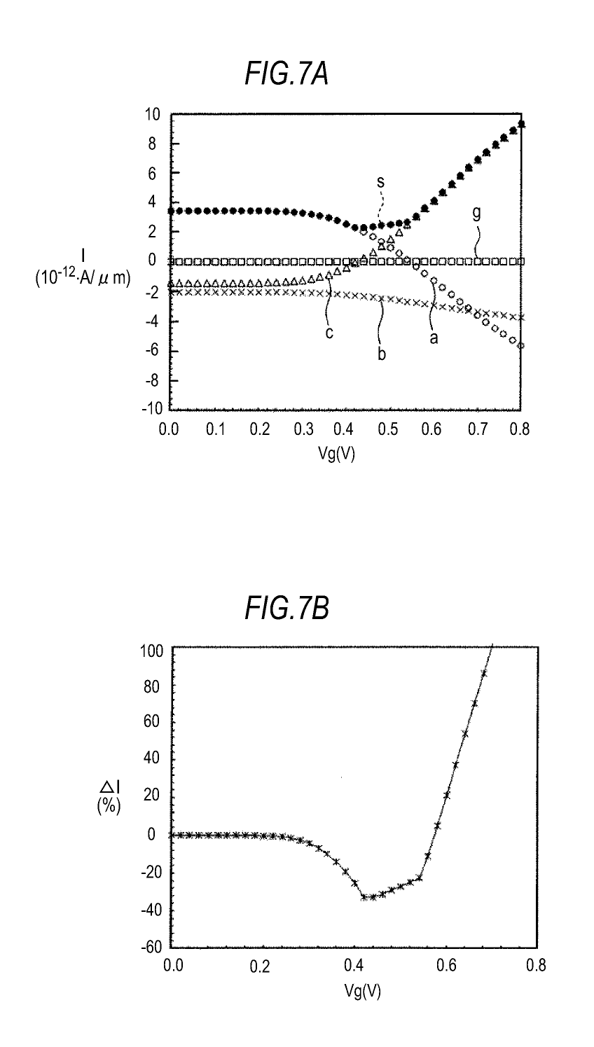

FIGS. 7A and 7B show current-voltage characteristics associated with the embodiment of the present disclosure.

FIG. 7A is a graph showing currents at the anode terminal (a), the cathode terminal (c), the gate terminal (g), and a body terminal (b) and a consumed current (the sum of currents flowing into the diode (represented by s) plotted with respect to the gate voltage Vg.

FIG. 7B is a graph showing amounts of fluctuation ΔI of the consumed current plotted with respect to the gate voltage Vg.

When a fixed voltage is applied to the anode of the gate type diode, the dependence of the current at each terminal of the diode on the gate voltage Vg temporarily reduces as the gate voltage is increased by the consumed current that is the sum of currents flowing into the diode. However, the dependence increases when the gate voltage reaches a certain value at which a leak current flows through the PN junction in the opposite direction.

As indicated by the arrow in FIG. 7B, a reduction of about 33% in the consumed current occurs in the region where the consumed current becomes smallest.

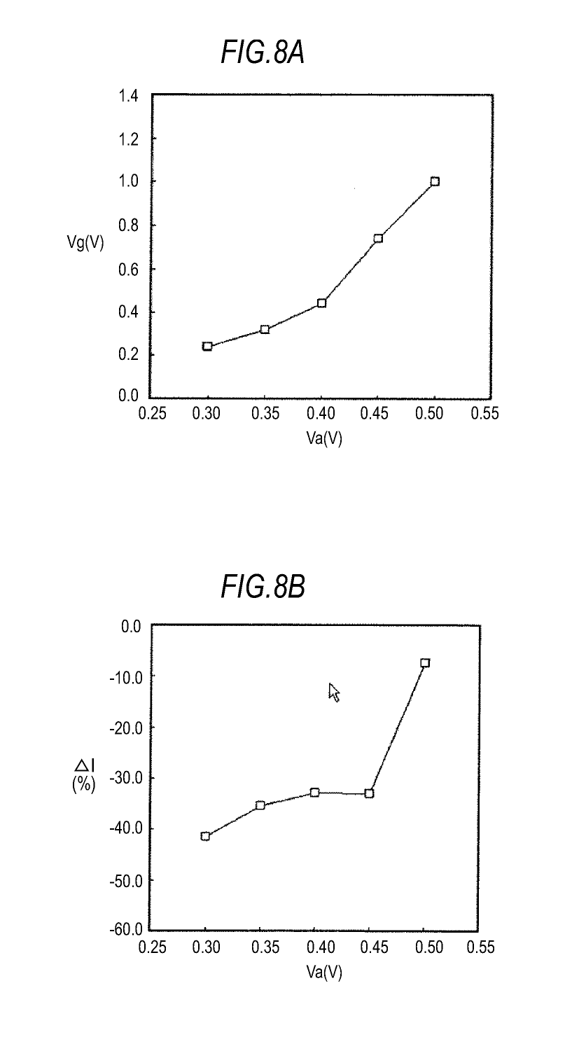

FIGS. 8A and 8B show current-voltage characteristics associated with the embodiment of the present disclosure.

FIG. 8A is a graph showing gate voltages Vg at which the consumed current is minimized, the gate voltages being plotted with respect to the anode voltage Va. Here, gate length Lg is set to 0.3 μm.

FIG. 8B is a graph showing amounts of fluctuation ΔI of the consumed current plotted with respect to the anode voltage Va.

A reduction of about 40 to 33% in the consumed current occurs when the anode voltage Va is in the range from 0.3 to 0.45 V.

### Second Embodiment

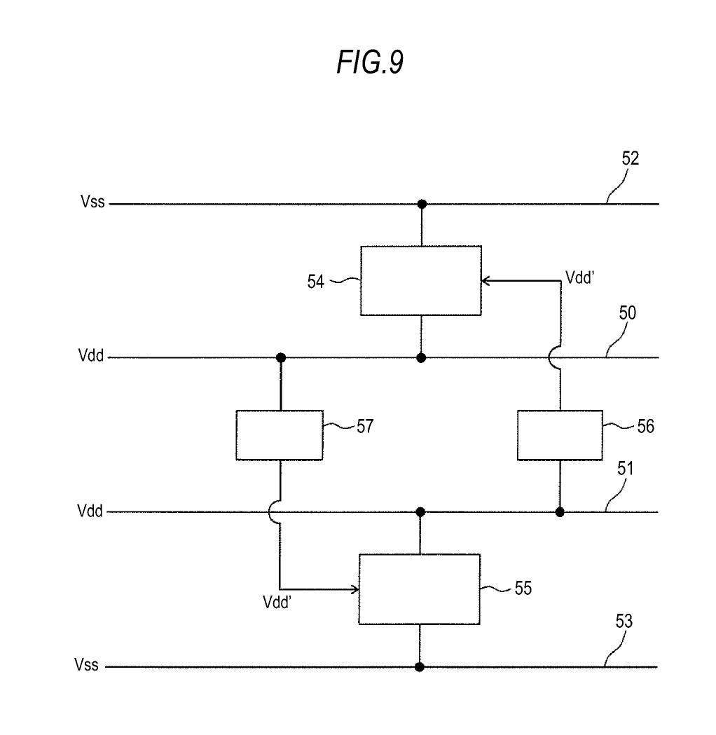

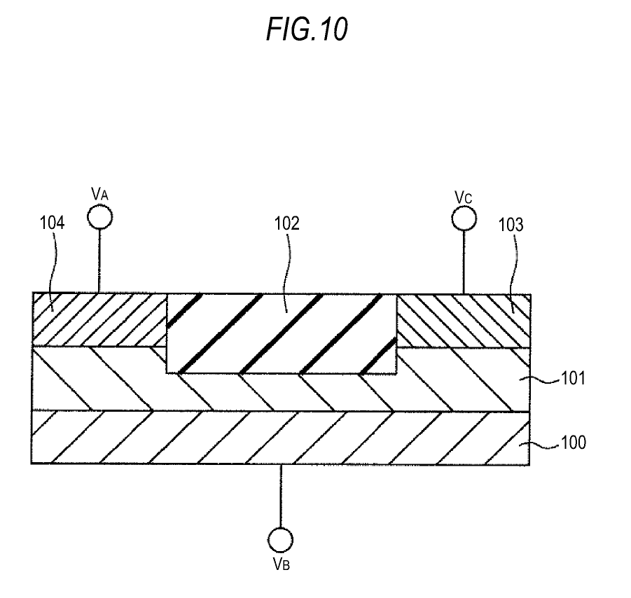

FIG. 9 is a schematic configuration diagram of a semiconductor device according to a second embodiment of the present disclosure.

The present embodiment includes two power supply lines 50 and 51 ad two ground lines 52 and 53, an ESD protection element 54 provided between the power supply line 50 and the ground line 52, and an ESD protection element 55 provided between the power supply line 51 and the ground line 53.

A voltage Vdd is supplied to the power supply lines 50, 51. The ground lines 52 and 53 are connected to ground Vss.

A step-down circuit 56 is connected to the power supply line 51 to step down the voltage Vdd into a voltage Vdd′ which is then connected to the ESD protection element 54. Similarly, a step-down circuit 57 is connected to the power supply line 50 to step down the voltage Vdd into a voltage Vdd′ which is the connected to the ESD protection element 55.

The embodiment is similar to the above-described embodiment in that it has a configuration in which a voltage Vdd′ obtained by stepping down a voltage Vdd is connected to a gate electrode of a trigger diode of an ESD protection element.

In the semiconductor device of the present embodiment, a power supply line different from a power supply line connected to an ESD protection element is connected to a gate electrode of a trigger diode forming part of the ESD protection element through a step-down circuit.

A predetermined stepped down voltage from the power supply line different from the power supply line connected to the ESD protection element is applied to the gate electrode of the trigger diode.

In order to supply a voltage Vdd′ obtained by stepping down a voltage Vdd, a power supply line different from a power supply line connected to an ESD protection element is required. In the present embodiment, a stepped down voltage can be obtained only by adding a step-down circuit between two pairs of power supply lines and ground lines forming an electronic circuit.

The embodiment of the present disclosure is not limited to the above description.

For example, the gate type diode may be configured in various ways in terms of the provision of the extension regions or the profile of impurities.

The present disclosure contains subject matter related to that disclosed in Japanese Priority Patent Application JP 2010-139851 filed in the Japan Patent Office on Jun. 18, 2010, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a semiconductor substrate having an electronic circuit including a power supply line and a ground line formed thereon; and
an electrostatic discharge protection element provided between the power supply line and the ground line on the semiconductor substrate, the electrostatic discharge protection element including a thyristor and a trigger diode driving the thyristor, wherein
the trigger diode includes an anode diffusion layer formed on the semiconductor substrate, a cathode diffusion layer formed on the semiconductor substrate apart from the anode diffusion layer, and a gate electrode formed between the anode diffusion layer and the cathode diffusion layer on the semiconductor substrate, a gate insulation film being interposed between the semiconductor substrate and the trigger diode, and
an external terminal to be connected to an external power supply is electrically connected to the gate electrode.

2. A semiconductor device according to claim 1, wherein the gate electrode is in an electrically floating state before the supply of power to the semiconductor device is started.

3. A semiconductor device according to claim 1, wherein a predetermined voltage is applied to the gate electrode after the supply of power to the semiconductor device is started.

4. A semiconductor device according to claim 3, wherein
a power supply line separate from the power supply line and the gate electrode are connected through a step-down circuit; and
the predetermined voltage is a voltage obtained by stepping down a voltage on the separate power supply line.

5. A semiconductor device according to claim 4, further comprising:
a first power supply line and a second power supply line serving as the power supply line and a first ground line and a second ground line serving as the ground line;
a first electrostatic discharge protection element provided between the first power supply line and the first ground line and a second electrostatic discharge protection element provided between the second power supply line and the second ground line, the first and second electrostatic discharge protection elements serving as the electrostatic discharge protection element; and
a first step-down circuit connected to the first power supply line and a second step-down circuit connected to the second power supply line, wherein
a voltage obtained by stepping down a voltage on the first power supply line with the first step-down circuit is connected to the second electrostatic discharge protection circuit, and
a voltage obtained by stepping down a voltage on the second power supply line with the second step-down circuit is connected to the first electrostatic discharge protection circuit.

6. A semiconductor device according to claim 3, wherein the application of a predetermined voltage to the gate electrode decreases a potential at a region of the semiconductor substrate under the gate electrode to increase an on-state voltage of the trigger diode while the gate electrode is kept in the floating state.

7. A semiconductor device according to claim 1, wherein the trigger diode includes an n-type extension diffusion layer formed to extend in the semiconductor substrate from the cathode electrode to a region under the gate electrode and a p-type extension diffusion layer formed to extend from the anode electrode to the region under the gate electrode.
